(19) United States
(12) Patent Application Publication
(10) Pub. No.: US 2026/0301802 A1
(43) Pub. Date: Oct. 1, 2026

(54) STACKED FET SRAM WITH TOP-LAYER PASS-GATE

(71) Applicant: International Business Machines Corporation, Armonk, NY (US)

(72) Inventors: Chen Zhang, Santa Clara, CA (US); Junli Wang, Slingerlands, NY (US); Shay Reboh, Guilderland, NY (US); Shahrukh Khan, Sandy Hook, CT (US); Utkarsh Bajpai, Suffern, NY (US); Tenko Yamashita, Schenectady, NY (US)

(21) Appl. No.: 19/093,517

(22) Filed: Mar. 28, 2025

(51) Int. Cl. G11C 11/412; H10B 10/00; H10D 30/00; H10D 30/43; H10D 62/10; H10D 30/62

(52) U.S. Cl. CPC G11C 11/412; H10B 10/12; H10D 30/43; H10D 30/502; H10D 62/121; H10D 30/62

(57) ABSTRACT

Stacked field effect transistor (FET) static random access memory (SRAM) structures, circuits, and associated fabrication methods are presented. Recently there has been an emerging interest in considering stacked field effect transistor static random access memory bit-cell device designs that locate their pass-gate transistors on a top layer. This disclosure provides such designs. In particular, two x-couple implementations are presented that have their pass-gate transistors on a top layer. One implementation locates its x-couple between a top FET and a bottom FET. The other implementation locates its x-couple on the backside of the wafer.

### BACKGROUND

The present disclosure relates generally to the electrical, electronic, and computer arts. In particular, the present disclosure relates to stacked field effect transistor static random access memory having a top-layer pass-gate.

There is an ever-increasing demand for internet of things (IOT) devices. With increased IOT device demand comes increased demand for static random access memory devices.

### SUMMARY

Embodiments of the present disclosure include a semiconductor structure that includes a bottom device level including a first bottom field effect transistor (FET) of a first conductivity type, a second bottom FET of the first conductivity type, a third bottom FET of the first conductivity type, and a fourth bottom FET of the first conductivity type. The first bottom FET is electrically connected to the second bottom FET and the third bottom FET is electrically connected to the fourth bottom FET. The first bottom FET is located diagonally to the fourth bottom FET and the second bottom FET is located diagonally to the third bottom FET. The semiconductor structure also includes a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET. The first top FET and the fourth top FET are pass gates. The first top FET is electrically connected to the second top FET and the third top FET is electrically connected to the fourth top FET. The first bottom FET is a first dummy transistor which is wired to cross-couple with the third bottom FET and the fourth bottom FET is a second dummy transistor which is wired to cross-couple with the second bottom FET. The second bottom FET and the second top FET are wired to provide a first inverter and the third bottom FET and the third top FET are wired to provide a second inverter.

The above summary is not intended to describe each illustrated embodiment or every implementation of the present disclosure.

### BRIEF DESCRIPTION OF THE DRAWINGS

FIG. 1 is an illustration of a schematic view of a circuit in accordance with a first illustrative embodiment;

FIGS. 2A-2B are illustrations of layout views of a semiconductor structure in accordance with the first illustrative embodiment;

FIG. 3 is an illustration of a schematic view of a circuit in accordance with a second illustrative embodiment;

FIGS. 4A-4B are illustrations of layout views of a semiconductor structure in accordance with the second illustrative embodiment;

FIG. 5 is an illustration of a semiconductor structure following the performance of a finish bottom FET portion of a process flow in accordance with the first illustrative embodiment;

FIG. 6 is an illustration of a semiconductor structure following the performance of a form gate contact portion of a process flow in accordance with the first illustrative embodiment;

FIG. 7 is an illustration of a semiconductor structure following the performance of a finish top FET portion of a process flow in accordance with the first illustrative embodiment;

FIG. 8 is an illustration of a semiconductor structure following the performance of a form contacts portion of a process flow in accordance with the first illustrative embodiment;

FIG. 9 is an illustration of a semiconductor structure following the performance of a continue to finish backside contact portion of a process flow in accordance with the first illustrative embodiment;

FIG. 10 is an illustration of a semiconductor structure following the performance of a finish bottom FET portion of a process flow in accordance with the second illustrative embodiment;

FIG. 11 is an illustration of a semiconductor structure following the performance of a finish top FET portion of a process flow in accordance with the second illustrative embodiment;

FIG. 12 is an illustration of a semiconductor structure following the performance of a form contacts portion of a process flow in accordance with the second illustrative embodiment; and

FIG. 13 is an illustration of a semiconductor structure following the performance of a finish backside contact portion of a process flow in accordance with the second illustrative embodiment.

### DETAILED DESCRIPTION

Embodiments include a semiconductor structure, comprising: a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates, wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter. As a result, these illustrative embodiments provide a technical effect of a semiconductor structure where the first top FET and the fourth top FET are pass gates.

In some embodiments, the first conductivity type is n-type and the second conductivity type is p-type. As a result, these illustrative embodiments provide a technical effect of a semiconductor structure where the first conductivity type is n-type and the second conductivity type is p-type.

In some embodiments, the first conductivity type is p-type and the second conductivity type is n-type. As a result, these illustrative embodiments provide a technical effect of a semiconductor structure where the first conductivity type is p-type and the second conductivity type is n-type.

In some embodiments, each of the first bottom FET, the second bottom FET, the third bottom FET, the fourth bottom FET, the first top FET, the second top FET, the third top FET, and the fourth top FET are located on a semiconductor channel material structure. As a result, these illustrative embodiments provide a technical effect of a semiconductor structure where each of the first bottom FET, the second bottom FET, the third bottom FET, the fourth bottom FET, the first top FET, the second top FET, the third top FET, and the fourth top FET are located on a semiconductor channel material structure.

In some embodiments, the semiconductor channel material structure is a semiconductor fin. As a result, these illustrative embodiments provide a technical effect of a semiconductor structure where the semiconductor channel material structure is a semiconductor fin.

In some embodiments, the semiconductor channel material structure is a semiconductor nanowire. As a result, these illustrative embodiments provide a technical effect of a semiconductor structure where the semiconductor channel material structure is a semiconductor nanowire.

Embodiments include a semiconductor structure, comprising: a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates, wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter, wherein a first middle level contact is conductively coupled to a gate of the third bottom FET, and wherein the first middle level contact connects to both a gate of the first bottom FET and a first vertical S/D contact, forming a first middle level cross-couple. As a result, these illustrative embodiments provide a technical effect of a semiconductor structure where the first top FET and the fourth top FET are pass gates and wherein a first middle level contact is conductively coupled to a gate of the third bottom FET, and wherein the first middle level contact connects to both a gate of the first bottom FET and a first vertical S/D contact, forming a first middle level cross-couple.

Some embodiments further include a second middle level contact conductively coupled to a gate of the second bottom FET, wherein the second middle level contact connects to both a gate of the fourth bottom FET and a second vertical S/D contact, forming a second middle level cross-couple. As a result, these illustrative embodiments provide a technical effect of a semiconductor structure including a second middle level contact conductively coupled to a gate of the second bottom FET, wherein the second middle level contact connects to both a gate of the fourth bottom FET and a second vertical S/D contact, forming a second middle level cross-couple.

In some embodiments, each of the first bottom FET, the second bottom FET, the third bottom FET, the fourth bottom FET, the first top FET, the second top FET, the third top FET and the fourth top FET are located on a semiconductor channel material structure. As a result, these illustrative embodiments provide a technical effect of a semiconductor structure where each of the first bottom FET, the second bottom FET, the third bottom FET, the fourth bottom FET, the first top FET, the second top FET, the third top FET and the fourth top FET are located on a semiconductor channel material structure.

In some embodiments, the semiconductor channel material structure is a semiconductor fin. As a result, these illustrative embodiments provide a technical effect of a semiconductor structure where the semiconductor channel material structure is a semiconductor fin.

In some embodiments, the semiconductor channel material structure is a semiconductor nanowire. As a result, these illustrative embodiments provide a technical effect of a semiconductor structure where the semiconductor channel material structure is a semiconductor nanowire.

Embodiments include a semiconductor structure, comprising: a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates, wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter, wherein a first backside contact is conductively coupled to a gate of the third bottom FET, and wherein the first backside contact connects to both a gate of the first bottom FET and a drain epi of the second bottom FET, forming a first backside cross-couple. As a result, these illustrative embodiments provide a technical effect of a semiconductor structure where the first top FET and the fourth top FET are pass gates wherein a first backside contact is conductively coupled to a gate of the third bottom FET, and wherein the first backside contact connects to both a gate of the first bottom FET and a drain epi of the second bottom FET, forming a first backside cross-couple.

Some embodiments further include a second backside contact conductively coupled to a gate of the second bottom FET, and wherein the second backside contact connects to both a gate of the fourth bottom FET and a drain epi of the third bottom FET, forming a second backside cross-couple. As a result, these illustrative embodiments provide a technical effect of a semiconductor structure including a second backside contact conductively coupled to a gate of the second bottom FET, and wherein the second backside contact connects to both a gate of the fourth bottom FET and a drain epi of the third bottom FET, forming a second backside cross-couple.

In some embodiments, each of the first bottom FET, the second bottom FET, the third bottom FET, the fourth bottom FET, the first top FET, the second top FET, the third top FET and the fourth top FET are located on a semiconductor channel material structure. As a result, these illustrative embodiments provide a technical effect of a semiconductor structure where each of the first bottom FET, the second bottom FET, the third bottom FET, the fourth bottom FET, the first top FET, the second top FET, the third top FET, and the fourth top FET are located on a semiconductor channel material structure.

In some embodiments, the semiconductor channel material structure is a semiconductor fin. As a result, these illustrative embodiments provide a technical effect of a semiconductor structure where the semiconductor channel material structure is a semiconductor fin.

In some embodiments, the semiconductor channel material structure is a semiconductor nanowire. As a result, these illustrative embodiments provide a technical effect of a semiconductor structure where the semiconductor channel material structure is a semiconductor nanowire.

Embodiments include a semiconductor circuit, comprising: a bottom circuit level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and a top circuit level stacked above the bottom circuit level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates, wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter. As a result, these illustrative embodiments provide a technical effect of a semiconductor circuit where the first top FET and the fourth top FET are pass gates wherein a first middle level contact is conductively coupled to a gate of the third bottom FET, and wherein the first middle level contact connects to both a gate of the first bottom FET and a first vertical S/D contact, forming a first middle level cross-couple.

Some embodiments further include a first word line electrically connected to a gate of the first top FET and a second word line electrically connected to a gate of the fourth top FET. As a result, these illustrative embodiments provide a technical effect of a semiconductor circuit including a first word line electrically connected to a gate of the first top FET and a second word line electrically connected to a gate of the fourth top FET.

Some embodiments further include a first bit line electrically connected to a source/drain region of the first top FET and a second bit line electrically connected to a source/drain region of the fourth top FET. As a result, these illustrative embodiments provide a technical effect of a semiconductor circuit including a first bit line electrically connected to a source/drain region of the first top FET and a second bit line electrically connected to a source/drain region of the fourth top FET.

In some embodiments, the second top FET is connected to a first power source and the third top FET is connected to a second power source, and the second bottom FET is connected to ground and the third bottom FET is connected to ground. As a result, these illustrative embodiments provide a technical effect of a semiconductor circuit where the second top FET is connected to a first power source and the third top FET is connected to a second power source, and the second bottom FET is connected to ground and the third bottom FET is connected to ground.

Embodiments include a semiconductor circuit, comprising: a bottom circuit level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and a top circuit level stacked above the bottom circuit level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates, wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter, wherein a first middle level contact is conductively coupled to a gate of the third bottom FET, and wherein the first middle level contact connects to both a gate of the first bottom FET and a first vertical S/D contact, forming a first middle level cross-couple. As a result, these illustrative embodiments provide a technical effect of a semiconductor circuit where the first top FET and the fourth top FET are pass gates wherein a first backside contact is conductively coupled to a gate of the third bottom FET, and wherein the first backside contact connects to both a gate of the first bottom FET and a drain epi of the second bottom FET, forming a first backside cross-couple.

Some embodiments further include a second middle level contact conductively coupled to a gate of the second bottom FET, wherein the second middle level contact connects to both a gate of the fourth bottom FET and a second vertical S/D contact, forming a second middle level cross-couple. As a result, these illustrative embodiments provide a technical effect of a semiconductor circuit including a second middle level contact conductively coupled to a gate of the second bottom FET, wherein the second middle level contact connects to both a gate of the fourth bottom FET and a second vertical S/D contact, forming a second middle level cross-couple.

Some embodiments further include a first word line electrically connected to a gate of the first top FET and a second word line electrically connected to a gate of the fourth top FET. As a result, these illustrative embodiments provide a technical effect of a semiconductor circuit including a first word line electrically connected to a gate of the first top FET and a second word line electrically connected to a gate of the fourth top FET.

Some embodiments further include a first bit line electrically connected to a source/drain region of the first top FET and a second bit line electrically connected to a source/drain region of the fourth top FET. As a result, these illustrative embodiments provide a technical effect of a semiconductor circuit including a first bit line electrically connected to a source/drain region of the first top FET and a second bit line electrically connected to a source/drain region of the fourth top FET.

In some embodiments, the second top FET is connected to a first power source and the third top FET is connected to a second power source, and the second bottom FET is connected to ground and the third bottom FET is connected to ground. As a result, these illustrative embodiments provide a technical effect of a semiconductor circuit where the second top FET is connected to a first power source and the third top FET is connected to a second power source, and the second bottom FET is connected to ground and the third bottom FET is connected to ground.

Recently there has been an emerging interest to consider stacked field effect transistor (FET) static random access memory (SRAM) bit-cell device designs that locate their pass-gate transistors on a top layer. This disclosure provides such designs. In particular, two x-couple implementations are presented. A first implementation locates its x-couple between a top FET and a bottom FET. A second implementation locates its x-couple on the backside of the wafer.

The illustrative examples recognize and take into account several considerations. The illustrative examples recognize and take into account a stacked processor flow to make a resultingly new static random access memory. The illustrative examples recognize and take into account 2 designs for putting a pass-gate on a top layer of a stacked field effect transistor, static random access memory bit-cell semiconductor structure. In a first design, an x-couple is formed between a top field effect transistor and a bottom field effect transistor. In a second design, an x-couple is formed on a backside of a wafer.

The illustrative examples present semiconductor devices, circuits, and methods of forming semiconductor devices that provide a pass-gate on a top layer of a stacked field effect transistor, static random access memory bit-cell semiconductor structure.

It should be understood in advance that although this disclosure includes a detailed description of exemplary top layer pass-gate stacked field effect transistor, static random access memory bit-cell semiconductor structure architectures, embodiments of the invention are not limited to the particular top layer pass gate architectures described in this specification. Rather, embodiments of the present invention are capable of being implemented in conjunction with any other type of top layer pass gate architecture now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Transistors are semiconductor devices commonly found in a wide variety of integrated circuits (ICs). A transistor is effectively a switch. When a voltage is applied to a gate of the transistor that is greater than a threshold voltage, the switch is turned on, and current flows through the transistor. When the voltage at the gate is less than the threshold voltage, the switch is off, and current does not flow through the transistor.

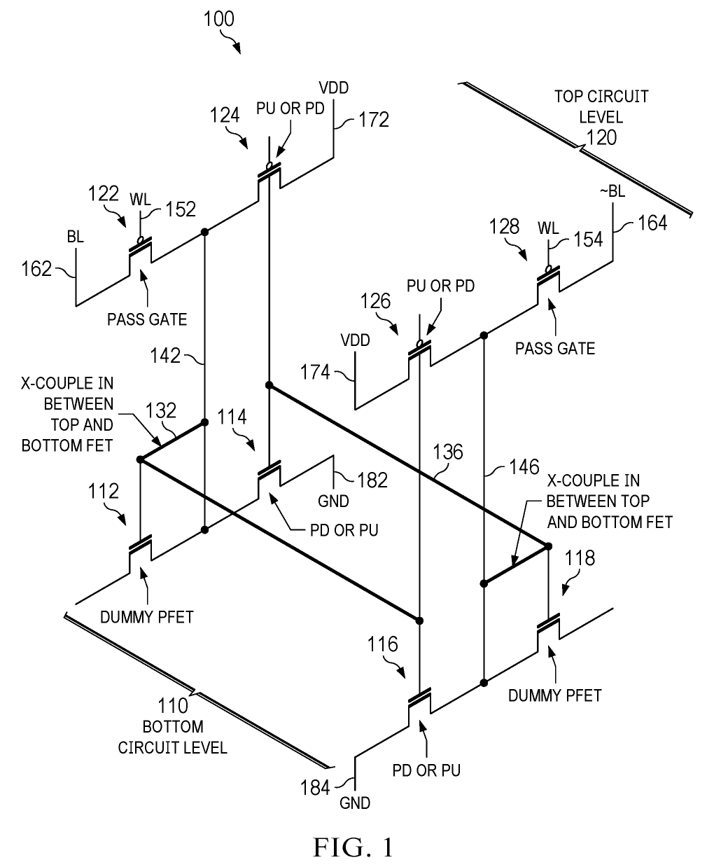

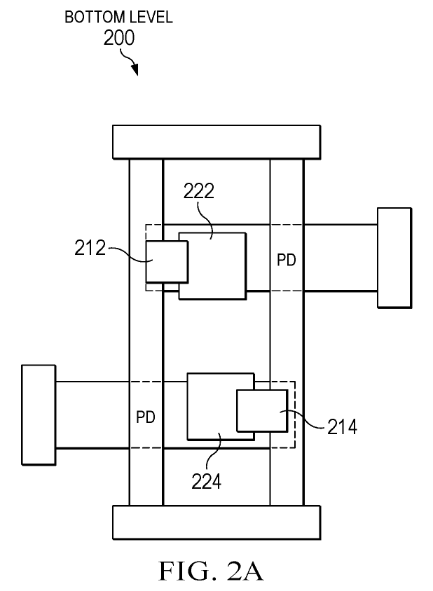

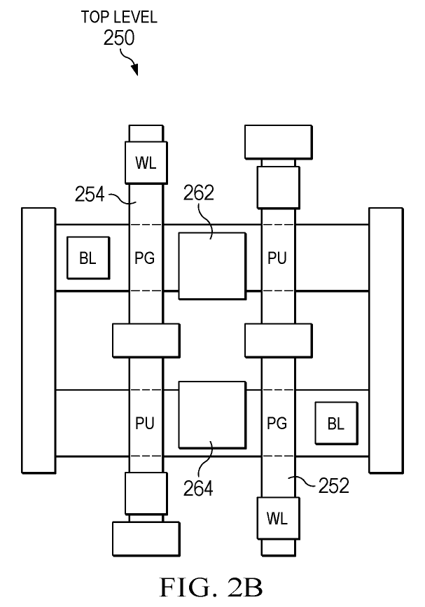

FIGS. 1-2B are illustrations of a first embodiment of a circuit and corresponding semiconductor structure including top pass gates and a middle x-couple pair.

Referring to FIG. 1, a circuit schematic of a first embodiment of this disclosure is illustrated including top pass gates and the middle x-couple pair. Semiconductor circuit 100 includes bottom circuit level 110. Bottom circuit level 110 includes a first bottom FET 112 of a first conductivity type, a second bottom FET 114 of the first conductivity type, a third bottom FET 116 of the first conductivity type, and a fourth bottom FET 118 of the first conductivity type. The first bottom FET 112 is electrically connected to the second bottom FET 114 and the third bottom FET 116 is electrically connected to the fourth bottom FET 118. The first bottom FET 112 is located diagonally to the fourth bottom FET 118 and the second bottom FET 114 is located diagonally to the third bottom FET 116.

Top circuit level 120 is stacked above the bottom circuit level 110. Top circuit level 120 includes first top FET 122 of a second conductivity type different from the first conductivity type located directly above the first bottom FET 112, a second top FET 124 of the second conductivity type located directly above the second bottom FET 114, a third top FET 126 of the second conductivity type located directly above the third bottom FET 116 , and a fourth top FET 128 of the second conductivity type located directly above the fourth bottom FET 118. The first top FET 122 and fourth top FET 128 are pass gates.

The first top FET 122 is electrically connected to the second top FET 124 and the third top FET 126 is electrically connected to the fourth top FET 128. The first bottom FET 112 is a first dummy transistor which is wired to cross-couple with the third bottom FET 116 and the fourth bottom FET 118 is a second dummy transistor which is wired to cross-couple with the second bottom FET 114. The second bottom FET 114 and the second top FET 124 are wired to provide a first inverter and the third bottom FET 116 and the third top FET 126 are wired to provide a second inverter. First middle level contact 132 is conductively coupled to a gate of the third bottom FET 116. The first middle level contact 132 connects to both a gate of the first bottom FET 112 and a first vertical S/D contact 142, forming a first middle level cross-couple.

Second middle level contact 136 is conductively coupled to a gate of the second bottom FET 114. The second middle level contact 136 connects to both a gate of the fourth bottom FET 118 and a second vertical S/D contact 146, forming a second middle level cross-couple.

A first word line 152 is electrically connected to a gate of the first top FET 122 and a second word line 154 is electrically connected to a gate of the fourth top FET 128. A first bit line 162 is electrically connected to a source/drain region of the first top FET 122 and a second bit line 164 is electrically connected to a source/drain region of the fourth top FET 128. The second top FET 124 is connected to a first power source 172 and the third top FET 126 is connected to a second power source 174. The second bottom FET 114 is connected to a first ground 182 and the third bottom FET 116 is connected to a second ground 184.

Referring to FIG. 2A, a bottom level layout 200 of the first embodiment of this disclosure is illustrated showing x-couple connectors 212, 214. Bottom level layout 200 includes inverter output node contacts 222, 224.

Referring to FIG. 2B, a top level layout 250 of the first embodiment of this disclosure is illustrated showing pass gates 252, 254. Top level layout 250 includes inverter output node contacts 262, 264.

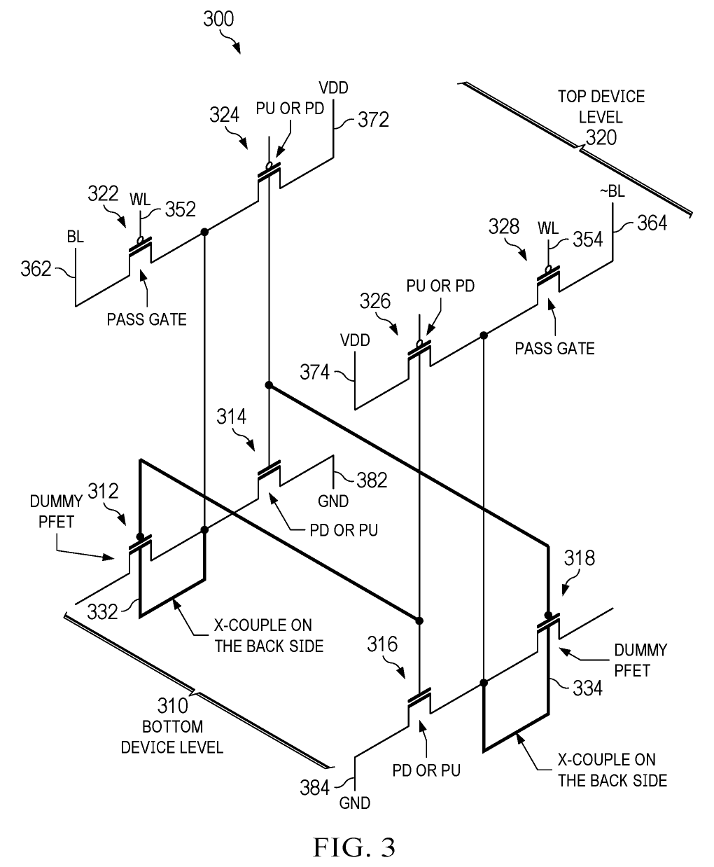

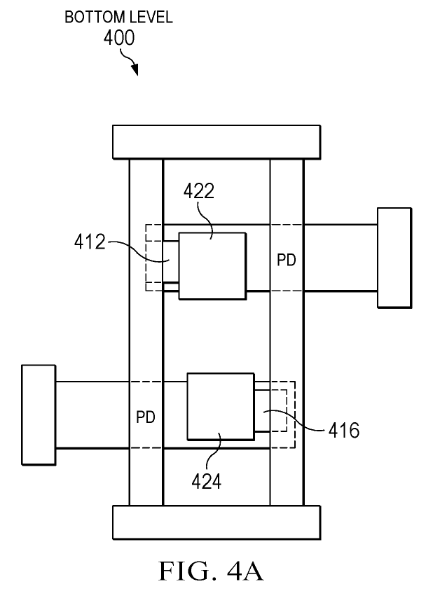

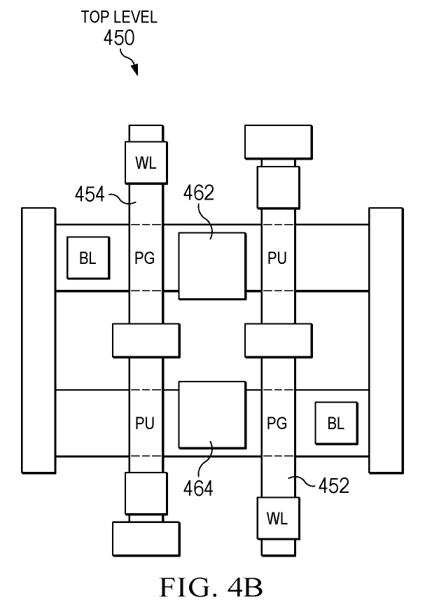

FIGS. 3-4B are illustrations of a second embodiment of a circuit and corresponding semiconductor structure including top pass gates and a backside x-couple pair.

Referring to FIG. 3, a circuit schematic of a second embodiment of this disclosure is illustrated including top pass gates and the backside x-couple pair. Semiconductor circuit 300 includes a bottom device level 310 including a first bottom FET 312 of a first conductivity type, a second bottom FET 314 of the first conductivity type, a third bottom FET 316 of the first conductivity type, and a fourth bottom FET 318 of the first conductivity type. The first bottom FET 312 is electrically connected to the second bottom FET 314 and the third bottom FET 316 is electrically connected to the fourth bottom FET 318. The first bottom FET 312 is located diagonally to the fourth bottom FET 318 and the second bottom FET 314 is located diagonally to the third bottom FET 316. A top device level 320 is stacked above the bottom device level 310.

Top device level 320 includes a first top FET 322 of a second conductivity type different from the first conductivity type located directly above the first bottom FET 312, a second top FET 324 of the second conductivity type located directly above the second bottom FET 314, a third top FET 326 of the second conductivity type located directly above the third bottom FET 316, and a fourth top FET 328 of the second conductivity type located directly above the fourth bottom FET 318. The first top FET 322 and the fourth top FET 328 are pass gates.

The first top FET 322 is electrically connected to the second top FET 324 and the third top FET 326 is electrically connected to the fourth top FET 328. The first bottom FET 312 is a first dummy transistor which is wired to cross-couple with the third bottom FET 316 and the fourth bottom FET 318 is a second dummy transistor which is wired to cross-couple with the second bottom FET 314. The second bottom FET 314 and the second top FET 324 are wired to provide a first inverter and the third bottom FET 316 and the third top FET 326 are wired to provide a second inverter.

A first backside contact 332 is conductively coupled to a gate of the third bottom FET 316. The first backside contact 332 connects to both a gate of the first bottom FET 312 and a drain epi of the second bottom FET 314, forming a first backside cross-couple. A second backside contact 334 is conductively coupled to a gate of the second bottom FET 314. The second backside contact 334 connects to both a gate of the fourth bottom FET 318 and a drain epi of the third bottom FET 316, forming a second backside cross-couple.

A first word line 352 is electrically connected to a gate of the first top FET 322 and a second word line 354 is electrically connected to a gate of the fourth top FET 328. A first bit line 362 is electrically connected to a source/drain region of the first top FET 322 and a second bit line 364 is electrically connected to a source/drain region of the fourth top FET 328. The second top FET 324 is connected to a first power source 372 and the third top FET 326 is connected to a second power source 374. The second bottom FET 314 is connected to a first ground 382 and the third bottom FET 316 is connected to a second ground 384.

Referring to FIG. 4A, a bottom level layout 400 of the second embodiment of this disclosure is illustrated showing the x-couple connectors on a back side 412, 416. Bottom level layout 400 includes inverter output node contacts 422, 424.

Referring to FIG. 4B, a top level layout 450 of the first embodiment of this disclosure is illustrated showing the pass gates 452, 454. Top level layout 450 includes inverter output node contacts 462, 464.

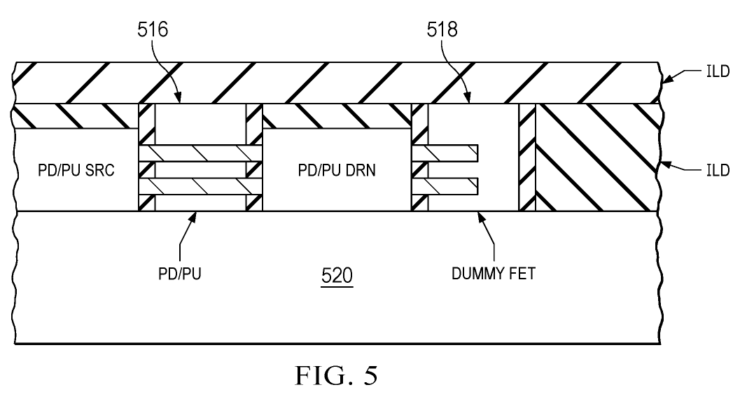

FIGS. 5-9 are illustrations of a silicon substrate during stages of forming pFET semiconductor devices and nFET semiconductor devices on the same substrate according to the first embodiment of the present disclosure.

Referring to FIG. 5, an illustration of a cross-sectional view of a semiconductor structure of a semiconductor wafer after a finish bottom FET fabrication stage is depicted in accordance with an illustrative embodiment. FET 516 and dummy FET 518 are formed on substrate 520.

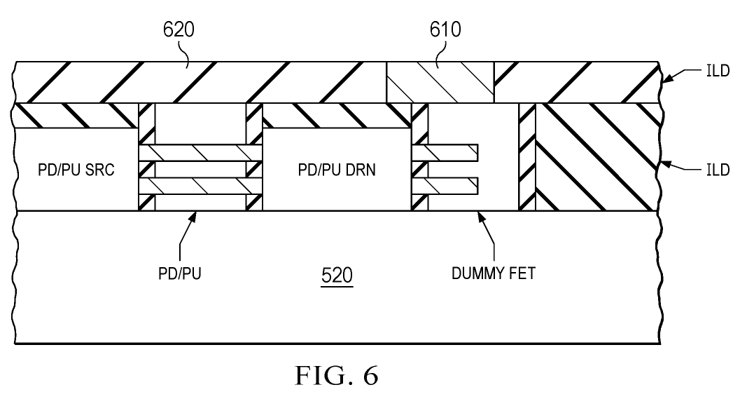

Referring to FIG. 6, an illustration of a cross-sectional view of a semiconductor structure of a semiconductor wafer after a form gate contact fabrication stage is depicted in accordance with an illustrative embodiment. Gate contact 610 is formed in interlayer dielectric 620.

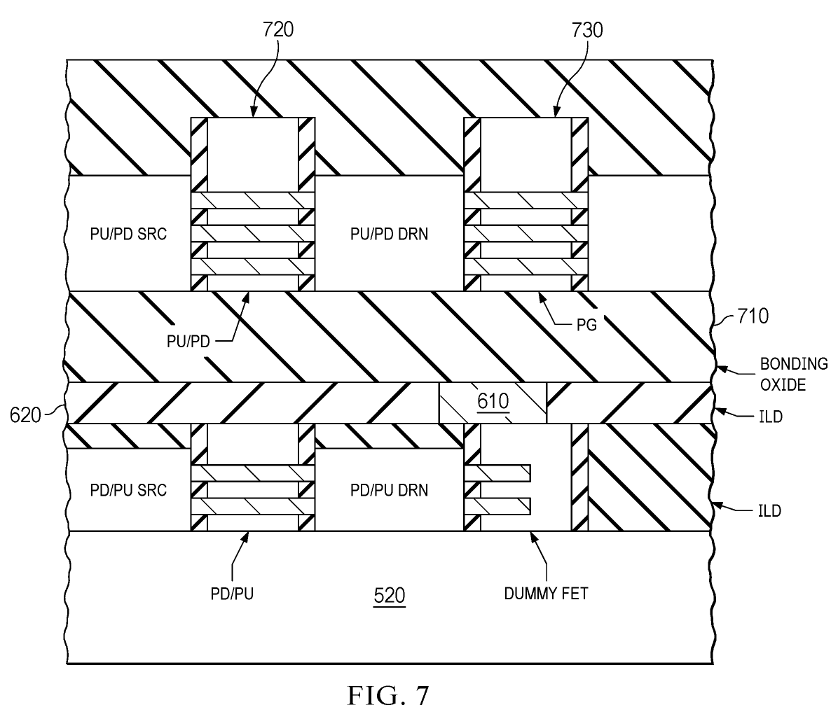

Referring to FIG. 7, an illustration of a cross-sectional view of a semiconductor structure of a semiconductor wafer after a finish top FET fabrication stage is depicted in accordance with an illustrative embodiment. Bonding oxide 710 is formed above gate contact 610 and interlayer dielectric 620. FET 720 and pass-gate FET 730 are formed above bonding oxide 710.

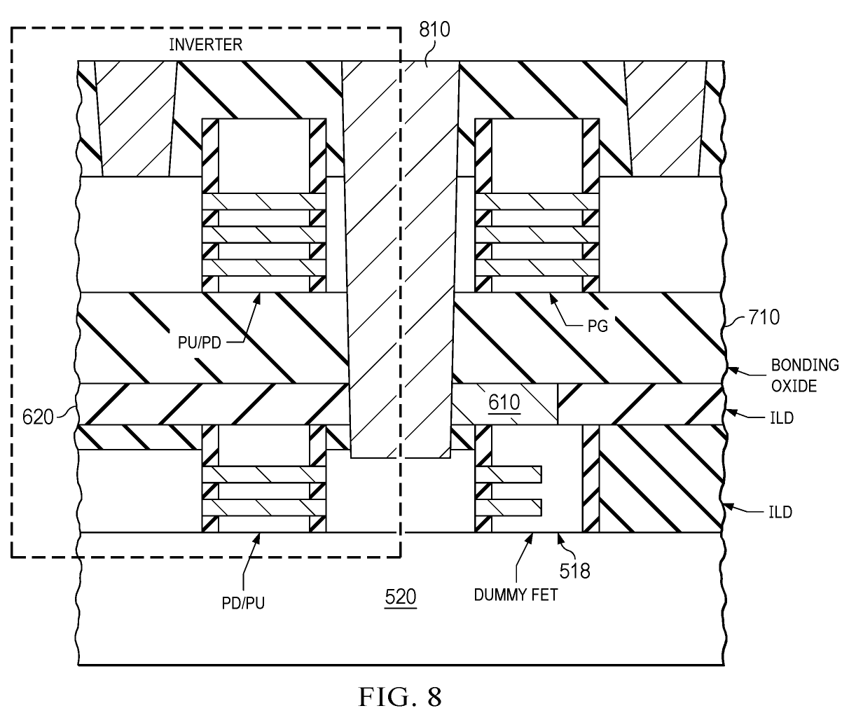

Referring to FIG. 8, an illustration of a cross-sectional view of a semiconductor structure of a semiconductor wafer after a form contacts fabrication stage is depicted in accordance with an illustrative embodiment. Output node 810 connects PU drain and PD drain together for the inverter in this cross section. Gate contact 610 connects and forms an x-couple connection. The dummy FET 518 gate is an extension of the input of the other inverter (not shown).

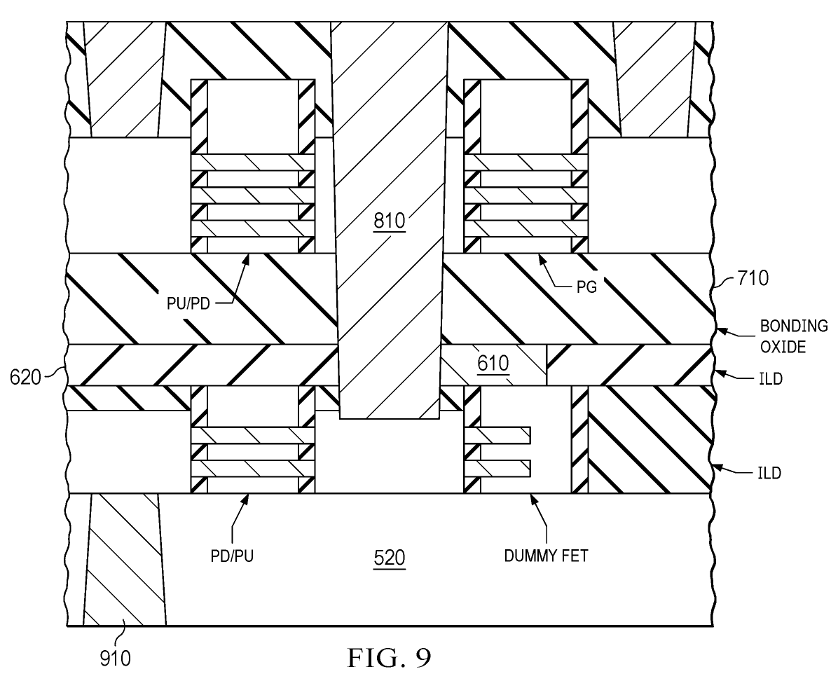

Referring to FIG. 9, an illustration of a cross-sectional view of a semiconductor structure of a semiconductor wafer after a continue to finish backside contact fabrication stage is depicted in accordance with an illustrative embodiment. Backside contact 910 is formed in substrate 520.

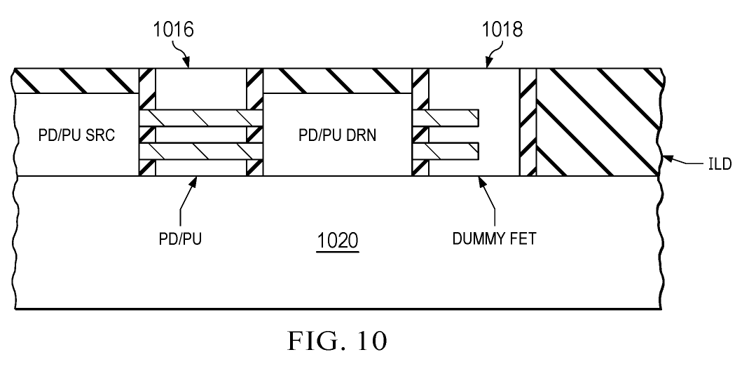

FIGS. 10-13 are illustrations of a silicon substrate during stages of forming pFET semiconductor devices and nFET semiconductor devices on the same substrate according to the second embodiment of the present disclosure.

Referring to FIG. 10, an illustration of a cross-sectional view of a semiconductor structure of a semiconductor wafer after a finish bottom FET fabrication stage is depicted in accordance with an illustrative embodiment. FET 1016 and dummy FET 1018 are formed on substrate 1020.

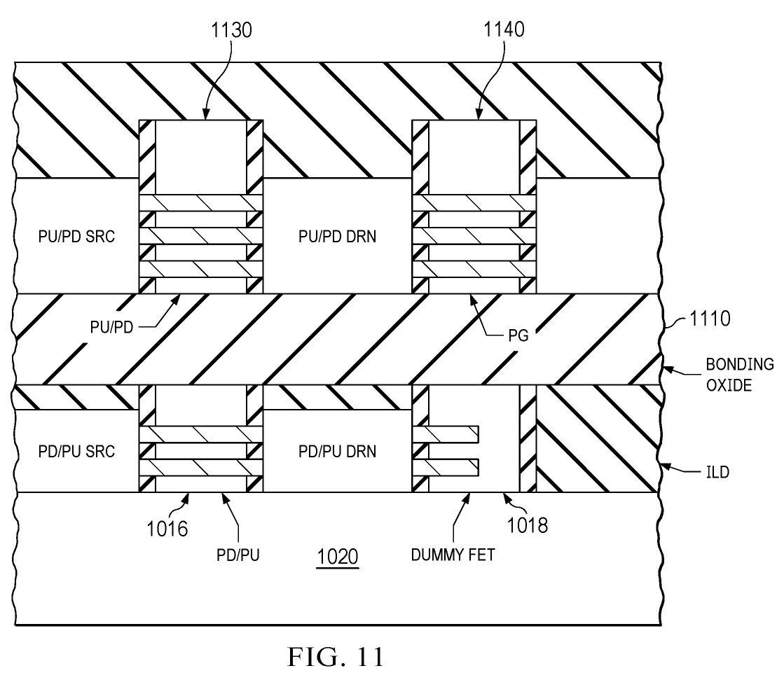

Referring to FIG. 11, an illustration of a cross-sectional view of a semiconductor structure of a semiconductor wafer after a finish top FET fabrication stage is depicted in accordance with an illustrative embodiment. Bonding oxide 1110 is formed above FET 1016 and dummy FET 1018. FET 1130 and pass-gate FET 1140 are formed above bonding oxide 1110.

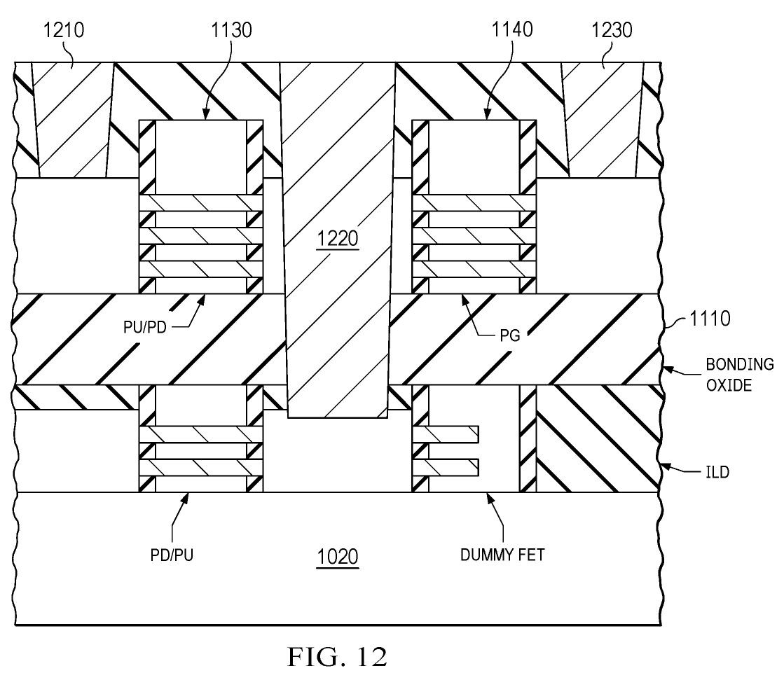

Referring to FIG. 12, an illustration of a cross-sectional view of a semiconductor structure of a semiconductor wafer after a form contacts fabrication stage is depicted in accordance with an illustrative embodiment. Contact 1210, 1220, and 1230 are formed.

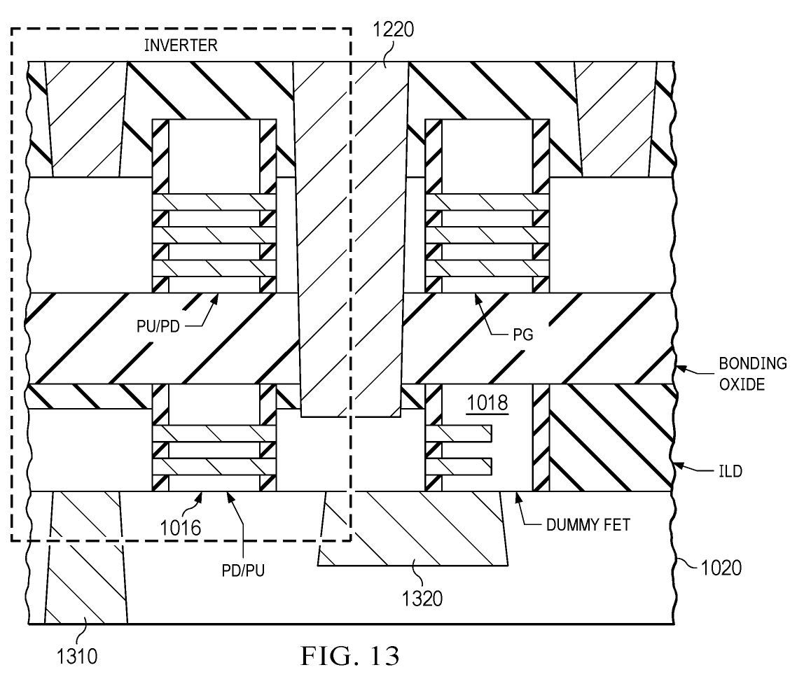

Referring to FIG. 13, an illustration of a cross-sectional view of a semiconductor structure of a semiconductor wafer after a finish backside contact fabrication stage is depicted in accordance with an illustrative embodiment. Backside contacts 1310, 1320 are formed in substrate 1020. Contact 1220 defines an output node that connects PU drain and PD drain together for the inverter in this cross section. A backside contact connects to both dummy FET 1018 gate and a drain epi of the FET 1016, forming an x-couple connection. The dummy FET 1018 gate is an extension of the input of the other inverter (not shown). Backside contact 1320 connects to both dummy FET 1018 gate and drain epi of the FET 1016, forming an x-couple connection.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and
a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates,
wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter.

2. The semiconductor structure of claim 1, wherein the first conductivity type is n-type and the second conductivity type is p-type.

3. The semiconductor structure of claim 1, wherein the first conductivity type is p-type and the second conductivity type is n-type.

4. The semiconductor structure of claim 1, wherein each of the first bottom FET, the second bottom FET, the third bottom FET, the fourth bottom FET, the first top FET, the second top FET, the third top FET, and the fourth top FET are located on a semiconductor channel material structure.

5. The semiconductor structure of claim 4, wherein the semiconductor channel material structure is a semiconductor fin.

6. The semiconductor structure of claim 4, wherein the semiconductor channel material structure is a semiconductor nanowire.

7. A semiconductor structure, comprising:
a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and
a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates,
wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter,
wherein a first middle level contact is conductively coupled to a gate of the third bottom FET, and
wherein the first middle level contact connects to both a gate of the first bottom FET and a first vertical S/D contact, forming a first middle level cross-couple.

8. The semiconductor structure of claim 7, further comprising
a second middle level contact conductively coupled to a gate of the second bottom FET,
wherein the second middle level contact connects to both a gate of the fourth bottom FET and a second vertical S/D contact, forming a second middle level cross-couple.

9. The semiconductor structure of claim 7, wherein each of the first bottom FET, the second bottom FET, the third bottom FET, the fourth bottom FET, the first top FET, the second top FET, the third top FET, and the fourth top FET are located on a semiconductor channel material structure.

10. The semiconductor structure of claim 9, wherein the semiconductor channel material structure is a semiconductor fin.

11. The semiconductor structure of claim 9, wherein the semiconductor channel material structure is a semiconductor nanowire.

12. A semiconductor structure, comprising:
a bottom device level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and
a top device level stacked above the bottom device level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates,
wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter,
wherein a first backside contact is conductively coupled to a gate of the third bottom FET, and
wherein the first backside contact connects to both a gate of the first bottom FET and a drain epi of the second bottom FET, forming a first backside cross-couple.

13. The semiconductor structure of claim 12, further comprising
a second backside contact conductively coupled to a gate of the second bottom FET, and
wherein the second backside contact connects to both a gate of the fourth bottom FET and a drain epi of the third bottom FET, forming a second backside cross-couple.

14. The semiconductor structure of claim 12, wherein each of the first bottom FET, the second bottom FET, the third bottom FET, the fourth bottom FET, the first top FET, the second top FET, the third top FET, and the fourth top FET are located on a semiconductor channel material structure.

15. The semiconductor structure of claim 14, wherein the semiconductor channel material structure is a semiconductor fin.

16. The semiconductor structure of claim 14, wherein the semiconductor channel material structure is a semiconductor nanowire.

17. A semiconductor circuit, comprising:
a bottom circuit level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and
a top circuit level stacked above the bottom circuit level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates,
wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter.

18. The semiconductor circuit of claim 17, further comprising a first word line electrically connected to a gate of the first top FET and a second word line electrically connected to a gate of the fourth top FET.

19. The semiconductor circuit of claim 17, further comprising a first bit line electrically connected to a source/drain region of the first top FET and a second bit line electrically connected to a source/drain region of the fourth top FET.

20. The semiconductor circuit of claim 17, wherein the second top FET is connected to a first power source and the third top FET is connected to a second power source, the second bottom FET is connected to ground and the third bottom FET is connected to ground.

21. A semiconductor circuit, comprising:
a bottom circuit level including a first bottom field effect transistor (FET) of a first conductivity type, a second bottom FET of the first conductivity type, a third bottom FET of the first conductivity type, and a fourth bottom FET of the first conductivity type, wherein the first bottom FET is electrically connected to the second bottom FET and the third bottom FET is electrically connected to the fourth bottom FET, and the first bottom FET is located diagonally to the fourth bottom FET and the second bottom FET is located diagonally to the third bottom FET; and
a top circuit level stacked above the bottom circuit level and including a first top FET of a second conductivity type different from the first conductivity type located directly above the first bottom FET, a second top FET of the second conductivity type located directly above the second bottom FET, a third top FET of the second conductivity type located directly above the third bottom FET, and a fourth top FET of the second conductivity type located directly above the fourth bottom FET, and the first top FET and the fourth top FET are pass gates,
wherein the first top FET is electrically connected to the second top FET and the third top FET is electrically connected to the fourth top FET, and the first bottom FET is a first dummy transistor which is wired to cross-couple with the third bottom FET and the fourth bottom FET is a second dummy transistor which is wired to cross-couple with the second bottom FET, and the second bottom FET and the second top FET are wired to provide a first inverter and the third bottom FET and the third top FET are wired to provide a second inverter,
wherein a first middle level contact is conductively coupled to a gate of the third bottom FET, and
wherein the first middle level contact connects to both a gate of the first bottom FET and a first vertical S/D contact, forming a first middle level cross-couple.

22. The semiconductor circuit of claim 21, further comprising
a second middle level contact conductively coupled to a gate of the second bottom FET,
wherein the second middle level contact connects to both a gate of the fourth bottom FET and a second vertical S/D contact, forming a second middle level cross-couple.

23. The semiconductor circuit of claim 21, further comprising a first word line electrically connected to a gate of the first top FET and a second word line electrically connected to a gate of the fourth top FET.

24. The semiconductor circuit of claim 21, further comprising a first bit line electrically connected to a source/drain region of the first top FET and a second bit line electrically connected to a source/drain region of the fourth top FET.

25. The semiconductor circuit of claim 21, wherein the second top FET is connected to a first power source and the third top FET is connected to a second power source, the second bottom FET is connected to ground and the third bottom FET is connected to ground.
